(19) United States
(12) Patent Application Publication
(10) Pub. No.: US 2024/0153860 A1
(43) Pub. Date: May 9, 2024

(54) ELECTRONIC DEVICE

(71) Applicant: InnoLux Corporation, Miao-Li County (TW)

(72) Inventors: Te-Hsun LIN, Miao-Li County (TW); Wen-Hsiang LIAO, Miao-Li County (TW); Yung-Feng CHEN, Miao-Li County (TW); Ming-Hsien SHIH, Miao-Li County (TW)

(21) Appl. No.: 18/069,290

(22) Filed: Dec. 21, 2022

(30) Foreign Application Priority Data
Nov. 8, 2022 (CN) 202211391129.0

(51) Int. Cl. H01L 23/498; H01L 23/00; H01L 25/10

(52) U.S. Cl. CPC H01L 23/49844; H01L 23/49816; H01L 24/16; H01L 24/17; H01L 24/32; H01L 24/73; H01L 25/105; H01L 23/49833; H01L 2224/16013; H01L 2224/16105; H01L 2224/16227; H01L 2224/17104; H01L 2224/32225; H01L 2224/73204; H01L 2225/1023; H01L 2225/1041; H01L 2225/1058; H01L 2225/1094; H01L 2924/182; H01L 2924/35121

(57) ABSTRACT

An electronic device is provided. The electronic device includes a redistribution structure, an electronic unit and a first conductive pad. The first conductive pad is disposed between the redistribution structure and the electronic unit. The electronic unit is electrically connected to the redistribution structure through the first conductive pad. The first conductive pad has a first coefficient of thermal expansion and a first Young's modulus. The first coefficient of thermal expansion and the first Young's modulus conform to the following formula: 0.7×(0.0069E²−1.1498E+59.661)≤CTE≤1.3×(0.0069E²−1.1498E+59.661), wherein CTE is the first coefficient of thermal expansion, and E is the first Young's modulus in the formula.

### CROSS REFERENCE TO RELATED APPLICATIONS

This application claims the benefit of China Application No. 202211391129.0, filed Nov. 8, 2022, the entirety of which is incorporated by reference herein.

### BACKGROUND

### Technical Field

The present disclosure is related to an electronic device, and in particular it is related to the conductive pad structure of an electronic device.

### Description of the Related Art

Fan-out packaging technology, such as fan-out panel level packaging (FOPLP) technology or fan-out wafer level packaging (FOWLP) technology, can enhance the integration density of electronic components (e.g., transistors, diodes, resistors, capacitors, etc.) in a given area. Such fan-out packaging technology has been widely used in the production and manufacture of electronic devices in recent years.

However, a fan-out packaging structure has many integration structures of heterogeneous material interface (for example, the interface between the redistribution layer (RDL) and the conductive pad, the under bump metallurgy (UBM) region, etc.), the interface of heterogeneous materials is often prone to experiencing problems such as delamination or peeling due to the existence of large amounts of stress.

In view of the foregoing, developing a packaging structure that can improve the reliability of electronic devices (for example, reducing the stress on the heterogeneous interface structure) is still one of the current research topics in the industry.

### SUMMARY

In accordance with some embodiments of the present disclosure, an electronic device is provided. The electronic device includes a redistribution structure, an electronic unit and a first conductive pad. The first conductive pad is disposed between the redistribution structure and the electronic unit. The electronic unit is electrically connected to the redistribution structure through the first conductive pad. The first conductive pad has a first coefficient of thermal expansion and a first Young's modulus. The first coefficient of thermal expansion and the first Young's modulus conform to the following formula: 0.7×(0.0069E²−1.1498E+59.661)≤CTE≤1.3×(0.0069E²−1.1498E+59.661) wherein CTE is the first coefficient of thermal expansion, and E is the first Young's modulus in the formula.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a partial cross-sectional diagram of an electronic device in accordance with some embodiments of the present disclosure;

FIG. 2 is a partially enlarged diagram of region R1 in FIG. 1 in accordance with some embodiments of the present disclosure;

FIG. 3A is the result of stress simulation analysis at position P1 of an electronic device in accordance with some embodiments of the present disclosure;

FIG. 3B is the result of stress simulation analysis at position P2 of an electronic device in accordance with some embodiments of the present disclosure;

FIG. 3C is the result of stress simulation analysis at position P1 and position P2 of an electronic device in accordance with some embodiments of the present disclosure;

FIG. 4 is a partial cross-sectional diagram of an electronic device in accordance with some embodiments of the present disclosure;

FIG. 5 is a partial cross-sectional diagram of an electronic device in accordance with some embodiments of the present disclosure;

FIG. 6 is a partial cross-sectional diagram of an electronic device in accordance with some embodiments of the present disclosure.

### DETAILED DESCRIPTION

The electronic devices according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

The directional terms mentioned herein, such as “up”, “down”, “front”, “rear”, “left”, “right”, etc., are only referring to the directions of the accompanying drawings. Accordingly, the directional terms used are for illustration, not for limitation of the present disclosure.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “electrically coupled to” may include any direct or indirect electrical connection means.

In the following descriptions, terms “about” and “substantially” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with the embodiments of the present disclosure, an electronic device is provided, which includes a conductive pad with specific material properties, which can effectively reduce the stress on the heterogeneous interface structure, thereby improving the structural reliability of the electronic device.

In accordance with the embodiment of the present disclosure, the electronic device includes a semiconductor packaging structure, and the electronic device may include a display device, a backlight device, an antenna device, a touch device, a sensing device, a wearable device, a vehicle device, a battery device or a tiled device, but it is not limited thereto. The electronic device may be a bendable or flexible electronic device. The display device may be a non-self-luminous display device or a self-luminous display device. The antenna device may be a liquid-crystal type antenna device or a non-liquid crystal type antenna device. The sensing device may be a sensing device for sensing capacitance, light, heat or ultrasonic, but it is not limited thereto. Furthermore, the electronic device may, for example, include liquid crystal, quantum dot (QD), fluorescence, phosphor, another suitable material, or a combination thereof. The electronic device may include electronic components, and the electronic components may include passive components and active components, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs) or quantum dot light-emitting diodes (quantum dot LEDs), but they are not limited thereto. In accordance with some embodiments, the electronic device may include a panel and/or a backlight module. The panel may include, for example, a liquid-crystal panel or another self-luminous panel, but it is not limited thereto. The tiled device may be, for example, a tiled display device or a tiled antenna device, but it is not limited thereto. It should be understood that the electronic device may be any permutation and combination of the foregoing.

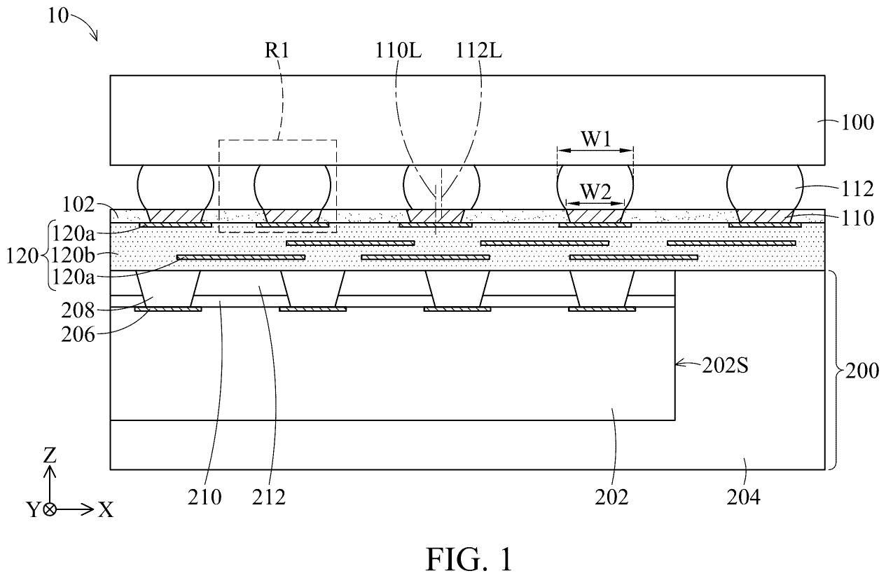

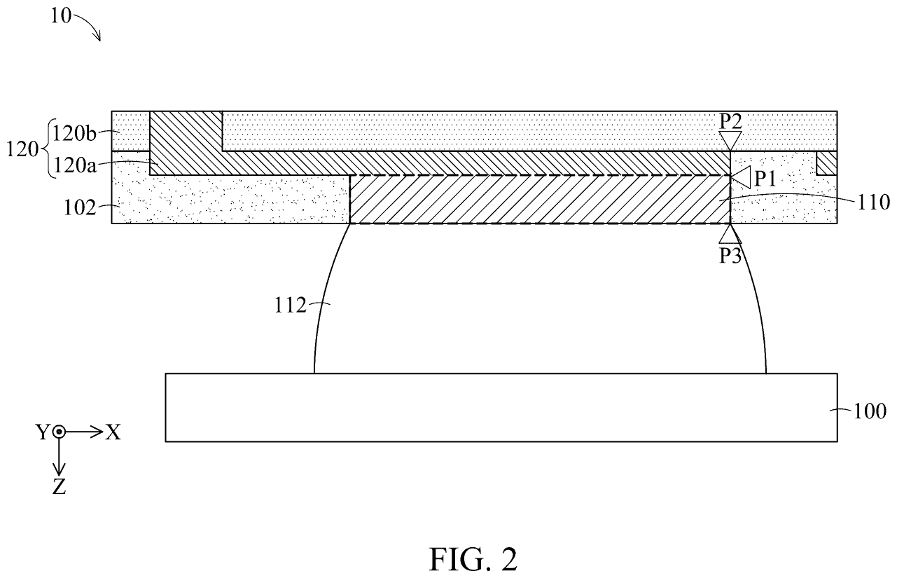

Refer to FIG. 1 and FIG. 2. FIG. 1 is a partial cross-sectional diagram of an electronic device 10 in accordance with some embodiments of the present disclosure. FIG. 2 is a partially enlarged diagram of region R1 in FIG. 1 (the region R1 shows an inverted structure) in accordance with some embodiments of the present disclosure. It should be understood that, some elements of the electronic device 10 may be omitted in the drawings for clarity, and only some elements are schematically shown. In accordance with some embodiments, additional features may be added to the electronic device 10 described below.

As shown in FIG. 1 and FIG. 2, the electronic device 10 includes an electronic unit 100, a redistribution structure 120 and a conductive pad 110. The conductive pad 110 is disposed between the redistribution structure 120 and the electronic unit 100, and the electronic unit 100 is electrically connected to the redistribution structure 120 through the conductive pad 110.

In accordance with some embodiments, the electronic unit 100 may include an integrated circuit (IC), a capacitor, a sensor, a capacitor, a resistor, a printed circuit board (PCB), a diode, another suitable electronic component, or a combination thereof, but it is not limited thereto. Furthermore, the number of electronic units is not limited to that shown in the drawings, and the electronic device may have any suitable number of electronic units according to different embodiments.

In accordance with some embodiments, the redistribution structure 120 includes at least one conductive layer 120a and at least one insulating layer 120b, and the conductive layer 120a and the insulating layer 120b are stacked alternately. The conductive pad 110 may be disposed on the conductive layer 120a and the insulating layer 120b. In accordance with some embodiments, the conductive layer 120a may be a single-layer or multi-layer structure, and the conductive layer 120a may include conductive materials, such as copper (Cu), titanium (Ti), aluminum (Al), tungsten (W), silver (Ag), gold (Au), tin (Sn), molybdenum (Mo), chromium (Cr), nickel (Ni), platinum (Pt), any metal alloy of the foregoing, another suitable material, or a combination thereof, but it is not limited thereto. In accordance with some embodiments, the conductive material may be formed by a physical vapor deposition process, an electroplating process, an electroless plating process, another suitable method, or a combination thereof. Moreover, the conductive material may be patterned by one or more photolithography processes and/or etching processes to form the patterned conductive layer 120a.

In accordance with some embodiments, the insulating layer 120b may include a polymer insulating material, for example, may include ABF build-up film (Ajinomoto Build-up Film, ABF), polybenzoxazole (PBO), polyimide (PI), photosensitive polyimide (PSPI), benzocyclobutene (BCB), another suitable insulating material or a combination thereof, but it is not limited thereto. In accordance with some embodiments, the insulating layer 120b may be formed by a coating process, a spin coating process, a chemical vapor deposition (CVD) process, another suitable method, or a combination thereof.

It should be understood that, according to different embodiments, the redistribution structure 120 may include any suitable number of conductive layers 120a and insulating layers 120b, for example, one or more conductive layers 120a and insulating layers 120b.

Moreover, in accordance with some embodiments, the electronic device 10 further includes an insulating layer 102 and a conductive pad 112. The insulating layer 102 may be disposed adjacent to the conductive pad 110 and the conductive pad 112. The conductive pad 112 may be disposed between the conductive pad 110 and the electronic unit 100, and the conductive pad 110 may be electrically connected to the electronic unit 100 through the conductive pad 112. In accordance with some embodiments, the conductive pad 110 is in contact with the insulating layer 102 and the conductive pad 112.

In accordance with some embodiments, the insulating layer 120 and the insulating layer 102 may have the same material. In accordance with some embodiments, the insulating layer 102 may be an encapsulation material or an underfill, which can reduce the effect of water and oxygen in the external environment on the conductive pad 110 and/or the conductive layer 120a, but it is not limited thereto. In accordance with some embodiments, the insulating layer 102 may include molding compound, epoxy, another suitable encapsulation material, or a combination thereof, but it is not limited thereto. The insulating layer 102 may include filler particles, such as silicon oxide, aluminum oxide, titanium oxide, another suitable material, or a combination thereof, but it is not limited thereto. In accordance with some embodiments, the insulating layer 102 may be formed by a compression molding process, a transfer molding process or another suitable method. In accordance with some embodiments, the insulating layer 102 may undergo a molding process in a liquid or semi-liquid state, and then be cured. In accordance with some embodiments, the insulating layer 102 may be filled between the redistribution structure 120 and the electronic unit 100, but it is not limited thereto.

In accordance with some embodiments, the conductive pad 112 can be a contact bump, and the conductive pad 110 can serve as an under bump metallurgy (UBM) to be electrically connected to the conductive pad 112, so that the redistribution structure 120 is electrically connected to the electronic unit 100. The conductive pad 112 may have a single-layer or multi-layer structure. In accordance with some embodiments, the material of the conductive pad 112 may include tin (Sn), nickel (Ni), gold (Au), silver (Ag), lead-free tin, copper (Cu), another suitable material, or a combination thereof, but it is not limited thereto. In accordance with some embodiments, the conductive pad 112 may be bonded to the conductive pad 110 by a reflow process, a fusion bonding process, a hybrid bonding process, a metal-to-metal bonding process, another suitable method, or a combination thereof.

It should be noted that, in accordance with some embodiments, the conductive pad 110 is a contact pad for external bonding of the packaging structure or the redistribution structure 120 to the electronic unit 100, and the conductive pad 110 is adjacent to the position of multiple heterogeneous interfaces, for example, the interface position between the conductive layer 120a and the conductive pad 110 (position P1), the interface position between the conductive layer 120a and the insulating layer 120b (position P2), and the interface position between the conductive pad 110 and the conductive pad 112 (position P3) etc. Problems such as delamination or peeling are prone to occur at positions adjacent to multiple heterogeneous interfaces. In this regard, embodiments of the present disclosure provide the pad 110 with specific material properties, which can effectively reduce the stress on the heterogeneous interface structure, thereby improving the structure reliability of the electronic device.

Specifically, the conductive pad 110 has a first coefficient of thermal expansion (CTE) and a first Young's modulus, and the first coefficient of thermal expansion and the first Young's modulus conform to the following formula: 0.7×(0.0069E²−1.1498E+59.661)≤CTE≤1.3×(0.0069E²−1.1498E+59.661). In the formula, CTE is the first coefficient of thermal expansion, and E is the first Young's modulus. In accordance with some embodiments, the first coefficient of thermal expansion and the first Young's modulus of the conductive pad 110 conform to the following formula: 0.8×(0.0069E²−1.1498E+59.661)≤CTE≤1.2×(0.0069E²−1.1498E+59.661). In accordance with some embodiments, the first coefficient of thermal expansion and the first Young's modulus of the conductive pad 110 conform to the following formula: 0.9×(0.0069E²−1.1498E+59.661)≤CTE≤1.1×(0.0069E²−1.1498E+59.661).

Furthermore, in accordance with some embodiments, the first coefficient of thermal expansion of the conductive pad 110 is greater than or equal to 10 ppm/° C. and less than or equal to 43.6 ppm/° C. (i.e. 10 ppm/° C.≤first coefficient of thermal expansion≤43.6 ppm/° C.). In accordance with some embodiments, the first Young's modulus of the conductive pad 110 is greater than or equal to 17 GPa and less than or equal to 89 GPa (i.e. 17 GPa≤first Young's modulus≤89 GPa). It should be noted that the conductive pad 110 with the aforementioned specific material properties can effectively reduce the stress on the heterogeneous interface structure. The risk of failure of the electronic device can be reduced.

In accordance with some embodiments, the conductive pad 112 has a second coefficient of thermal expansion, and the second coefficient of thermal expansion of the conductive pad 112 is greater than the first coefficient of thermal expansion of the conductive pad 110. Specifically, in accordance with some embodiments, the second coefficient of thermal expansion of the conductive pad 112 is greater than or equal to 15 ppm/° C. and less than or equal to 30 ppm/° C. (i.e. 15 ppm/° C.≤second coefficient of thermal expansion≤30 ppm/° C.)

In accordance with some embodiments, the aforementioned insulating layer 102 has a fourth coefficient of thermal expansion, and the fourth coefficient of thermal expansion of the insulating layer 102 is smaller than the first coefficient of thermal expansion of the conductive pad 110. Specifically, in accordance with some embodiments, the fourth coefficient of thermal expansion of the insulating layer 102 is greater than or equal to 5 ppm/° C. and less than or equal to 12 ppm/° C. (i.e. 5 ppm/° C.≤fourth coefficient of thermal expansion≤12 ppm/° C.).

In addition, in accordance with some embodiments, the aforementioned insulating layer 120b has a fifth coefficient of thermal expansion, and the fifth coefficient of thermal expansion of the insulating layer 120b is smaller than the first coefficient of thermal expansion of the conductive pad 110. Specifically, in accordance with some embodiments, the fifth coefficient of thermal expansion of the insulating layer 120b is greater than or equal to 5 ppm/° C. and less than or equal to 25 ppm/° C. (i.e. 5 ppm/° C.≤fifth coefficient of thermal expansion≤25 ppm/° C.).

In accordance with the embodiments of the present disclosure, the coefficient of thermal expansion of the element (e.g., the aforementioned conductive pad 110) can be measured by a look-up table, a thermal expansion analyzer or another known method. Furthermore, the Young's modulus of the element (e.g., the aforementioned conductive pad 110) can be measured by a look-up table, ASTM D638 standard method, or another known method. For example, the Young's modulus of the conductive pad 110 may be greater than or equal to 15 GPa and less than or equal to 25 GPa (i.e. 15 GPa≤Young's modulus of the conductive pad 110≤25 GPa).

In addition, in accordance with some embodiments, the material properties of the aforementioned conductive pad 110 can be obtained by performing stress simulation analysis on the heterogeneous interface structure of the electronic device. For example, it can be simulated by response surface methodology (RSM), but the present disclosure is not limited thereto. Specifically, in accordance with some embodiments, a response surface (with coefficient of thermal expansion, Young's modulus, and stress as parameters) formed by the specific heterogeneous interface structure of different materials in the electronic devices can be obtained by response surface methodology.

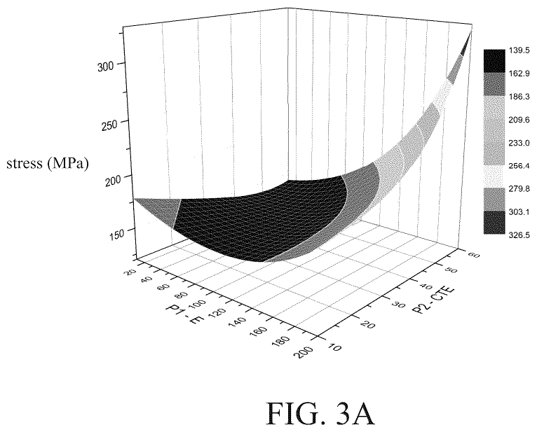

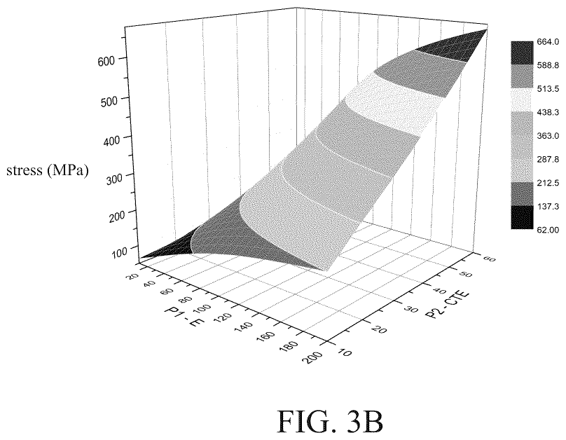

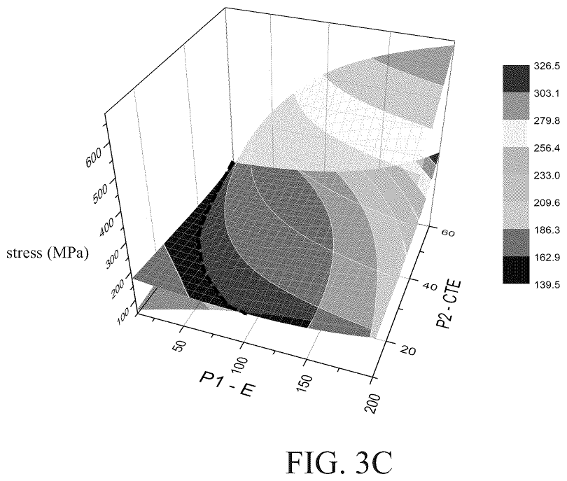

Refer to FIG. 3A to FIG. 3C. FIG. 3A is the result of stress simulation analysis at position P1 (the interface position between the conductive layer 120a and the conductive pad 110, as shown in FIG. 2) of the electronic device 10 in accordance with some embodiments of the present disclosure. FIG. 3B is the result of stress simulation analysis at position P2 (the interface position between the conductive layer 120a and the insulating layer 120b, as shown in FIG. 2) of the electronic device 10 in accordance with some embodiments of the present disclosure. FIG. 3C is the result of stress simulation analysis at position P1 and position P2 (as shown in FIG. 2) of the electronic device 10 in accordance with some embodiments of the present disclosure. FIG. 3C is an overlay of the results from FIG. 3A and FIG. 3B.

From FIG. 3A and FIG. 3B, the coefficients of thermal expansion, Young's modulus and stress on different materials at position P1 and position P2 of the electronic device 10 can be obtained, thereby obtaining the response surfaces at position P1 and position P2 respectively. Furthermore, the response surfaces of FIG. 3A and FIG. 3B can be superimposed to obtain the result of FIG. 3C. According to the result of FIG. 3C, the response surface range of the conductive pad 110 with low stress can be obtained, and the corresponding relation between the coefficient of thermal expansion and the Young's modulus that can achieve low interface stress can be obtained. Specifically, the conductive pad 110 having the material properties satisfying the formula: 0.7×(0.0069E²−1.1498E+59.661)≤CTE≤1.3×(0.0069E²−1.1498E+59.661) will have low interface stress.

In accordance with the embodiments of the present disclosure, the material of the conductive pad 110 may be any conductive material that meets the aforementioned formula: 0.7×(0.0069E²−1.1498E+59.661)≤CTE≤1.3×(0.0069E²−1.1498E+59.661). For example, the aforementioned conductive material may include copper alloy, magnesium alloy, zinc alloy, titanium alloy, or another conductive material conforming to the relational formula, but the present disclosure is not limited thereto. Furthermore, the conductive pad 110 may have a single-layer or multi-layer structure. In accordance with some embodiments, the conductive material may be formed by a physical vapor deposition process, an electroplating process, an electroless plating process, another suitable method, or a combination thereof. Moreover, one or more photolithography processes and/or etching processes may be used to pattern the conductive material to form the conductive pad 110.

As described above, the conductive pad 110 can serve as a contact pad for external bonding of the packaging structure to the electronic unit 100, and the conductive pad 110 is adjacent to a position of multiple heterogeneous interfaces. The aspects of application of the conductive pad 110 to electronic devices with different structures will be further described below.

As shown in FIG. 1, the electronic device 10 may further include a packaging structure 200, and the packaging structure 200 may be electrically connected to the redistribution structure 120. In accordance with some embodiments, the packaging structure 200 may include a chip 202 and a protective layer 204, and the protective layer 204 may surround the chip 202. Specifically, the protective layer 204 surrounds the chip 202 means that the protective layer 204 at least contacts two side surfaces of the chip 202 in a cross-sectional view. In accordance with some embodiments, the protective layer 204 surrounds at least one chip 202. In accordance with some embodiments, the protective layer 204 simultaneously surrounds at least one chip 202, and a resistor, a capacitor, an inductor, an antenna element or another suitable electronic component, but it is not limited thereto. In other words, the chip, resistor, capacitor, inductor, antenna element or another suitable electronic component may be electrically connected to the redistribution structure or electrically connected to each other through the redistribution structure, but it is not limited thereto.

In accordance with some embodiments, the electronic device 10 may be packaged in the manner of System-on-Chip (SoP), System-in-Package (SiP) or another suitable method. Moreover, in accordance with some embodiments, the manufacturing method of the electronic device 10 can be applied to wafer level package (WLP) or panel level package (PLP), etc., but the present disclosure is not limited thereto.

In accordance with some embodiments, the chip 202 may be, for example, a known-good die (KGD), an integrated circuit chip (IC), a diode and the like.

In accordance with some embodiments, the protective layer 204 may be an encapsulation material, which can reduce the chip 202 from being affected by water and oxygen in the external environment, but it is not limited thereto. In accordance with some embodiments, the protective layer 204 may include molding compound, epoxy, another suitable encapsulation material, or a combination thereof, but it is not limited thereto. In accordance with some embodiments, the protective layer 204 may be formed by a compression molding process, a transfer molding process or another suitable method. In accordance with some embodiments, the protective layer 204 may undergo a molding process in a liquid or semi-liquid state, and then be cured. The protective layer 204 may include filler particles, such as silicon oxide, aluminum oxide, titanium oxide, another suitable material, or a combination thereof, but it is not limited thereto. In accordance with some embodiments, the particle size of the filler particles of the protective layer 204 is greater than or equal to the particle size of the filler particles of the insulating layer 102, so that the protective layer 204 can have good rigidity, prevent the packaging device from being scratched or reduce the influence of water and oxygen on the chip 202 from the external environment, but it is not limited thereto.

In accordance with some embodiments, the protective layer 204 has a third coefficient of thermal expansion, and the third coefficient of thermal expansion of the protective layer 204 is smaller than the first coefficient of thermal expansion of the conductive pad 110. Specifically, in accordance with some embodiments, the third coefficient of thermal expansion of the protective layer 204 is greater than or equal to 6 ppm/° C. and less than or equal to 24 ppm/° C. (i.e. 6 ppm/° C.≤third coefficient of thermal expansion≤24 ppm/° C.).

In addition, in this embodiment, the electronic device 10 is packaged in a chip-first manner. That is, the packaging structure 200 including the chip 202 is formed first, and then the redistribution structure 120 on the packaging structure 200 is formed, but the present disclosure is not limited thereto. The chip-first packaging may further include face-up and face-down manners.

As shown in FIG. 1, in accordance with some embodiments, the packaging structure 200 may further include a conductive pad 206, a connecting member 208, a passivation layer 210 and an insulating layer 212. The conductive pad 206 and the connecting member 208 may be disposed between the chip 202 and the redistribution structure 120 to provide an electrical connection between the chip 202 and the redistribution structure 120. Furthermore, the passivation layer 210 and the insulating layer 212 may be disposed surrounding the conductive pad 206 and the connecting member 208.

In accordance with some embodiments, the material of the conductive pad 206 may include a conductive material, such as aluminum (Al), copper (Cu), tin (Sn), nickel (Ni), or any metal alloy of the foregoing, a transparent conductive material, or another suitable conductive material, but it is not limited to. In accordance with some embodiments, the conductive material may be formed by a physical vapor deposition process, an electroplating process, an electroless plating process, another suitable method, or a combination thereof. Moreover, the conductive material may be patterned by one or more photolithography and/or etching processes to form the conductive pad 206.

In accordance with some embodiments, the material of the connecting member 208 may include a conductive material, such as copper (Cu), titanium (Ti), aluminum (Al), tungsten (W), silver (Ag), gold (Au), tin (Sn), molybdenum (Mo), chromium (Cr), nickel (Ni), platinum (Pt), any metal alloy of the foregoing, another suitable material or a combination thereof, but it is not limited thereto. In accordance with some embodiments, the conductive material may be formed by a physical vapor deposition process, an electroplating process, an electroless plating process, another suitable method, or a combination thereof. Moreover, the conductive material may be patterned by one or more photolithography processes and/or etching processes to form the connecting member 208.

In accordance with some embodiments, the material of the passivation layer 210 may include an inorganic material, an organic material, or a combination thereof, but it is not limited thereto. For example, the inorganic material may include silicon nitride, silicon oxide, silicon oxynitride, another suitable material, or a combination thereof, but it is not limited thereto. For example, the organic material may include polyethylene terephthalate (PET), polyethylene (PE), polyethersulfone (PES), polycarbonate (PC), polymethylmethacrylate (PMMA), polyimide (PI), photosensitive polyimide (PSPI), another suitable material, or a combination thereof, but it is not limited thereto. Furthermore, the passivation layer 210 may have a single-layer or multi-layer structure. In accordance with some embodiments, the passivation layer 210 may be formed by a spin-coating process, a chemical vapor deposition (CVD) process, another suitable method, or a combination thereof.

In accordance with some embodiments, the insulating layer 212 may include a polymer insulating material, for example, may include ABF build-up film (Ajinomoto Build-up Film, ABF), polybenzoxazole (PBO), polyimide (PI), photosensitive polyimide (PSPI), benzocyclobutene (BCB), another suitable insulating material or a combination thereof, but it is not limited thereto. In accordance with some embodiments, the insulating layer 212 may be formed by a coating process, a spin coating process, a chemical vapor deposition (CVD) process, another suitable method, or a combination thereof.

In addition, as shown in FIG. 1, in accordance with some embodiments, the conductive pad 110 has a substantially planar top surface, and the top surface of the conductive pad 110 is substantially aligned with the top surface of the insulating layer 102. Moreover, the conductive pad 112 has a first width W1, and the conductive pad 110 has a second width W2. In accordance with some embodiments, the first width W1 of the conductive pad 112 is greater than the second width W2 of the conductive pad 110. In addition, in accordance with some embodiments, the centerline 110L of the conductive pad 110 and the centerline 112L of the conductive pad 112 do not overlap, and there is a distance between the centerline 110L and the centerline 112L. That is, an offset occurs when the conductive pad 110 is bonded to the conductive pad 112. In accordance with some embodiments, the distance between the centerline 110L and the centerline 112L does not exceed ⅙ of the width W2 of the conductive pad 110 (i.e. W2/6), and may be between 0 and W2/6. It should be noted that the slight offset of the conductive pad 110 and the conductive pad 112 can reduce the stress after the bonding reaction, but the offset distance should not be too large to affect the electrical connection. In accordance with some embodiments, the conductive pad 112 does not overlap with a side 202S of the chip 202. With such the design, the stress occurring during the manufacturing process can be reduced, thereby improving the reliability.

In accordance with the embodiments of the present disclosure, the first width W1 refers to the maximum width of the conductive pad 110 in the direction (for example, the X direction in the drawing) perpendicular to the normal direction of the electronic device (for example, the normal direction of the conductive pad 110). The second distance W2 refers to the maximum width of the conductive pad 112 in the direction (for example, the X direction in the drawing) perpendicular to the normal direction of the electronic device (for example, the normal direction of the conductive pad 110).

It should be understood that, in accordance with the embodiments of the present disclosure, a scanning electron microscope (SEM), an optical microscope (OM), a film thickness profiler (α-step), an ellipsometer or another suitable method can be used to measure the width, thickness, or height of an element, or the spacing or distance between elements. Specifically, in accordance with some embodiments, a scanning electron microscope can be used to obtain a cross-sectional image including the element to be measured, and the width, thickness, or height of an element, or the spacing or distance between elements in the image can be measured.

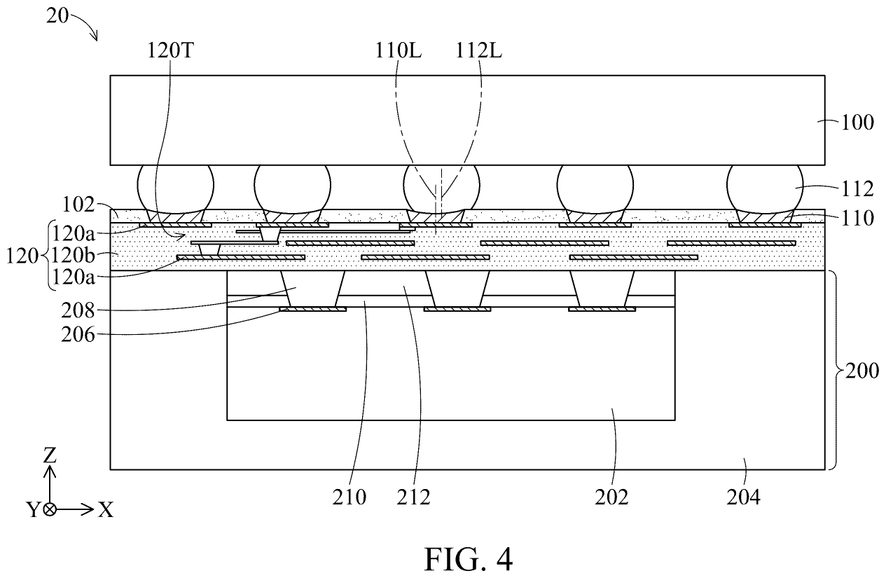

Next, refer to FIG. 4, which is a partial cross-sectional diagram of an electronic device 20 in accordance with some other embodiments of the present disclosure. It should be understood that, some elements of the electronic device 20 may be omitted in the drawings for clarity, and only some elements are schematically shown. In accordance with some embodiments, additional features may be added to the electronic device 20 described below. In addition, it should be understood that that the same or similar components or elements in the following paragraphs will be denoted by the same or similar reference numbers, and their materials, manufacturing methods and functions are the same or similar to those described above, and thus they will not be repeated hereafter.

As shown in FIG. 4, in accordance with some embodiments, the redistribution structure 120 may further include a thin-film transistor (TFT) unit 120T. The TFT unit 120T may be electrically connected to the conductive layer 120a in the redistribution structure 120, and then electrically connected to the conductive pad 110 and the electronic unit 100 for driving. In accordance with some embodiments, the TFT unit 120T may be further electrically connected to the signal lines of the electronic device. The signal lines may include, for example, current signal lines, voltage signal lines, high-frequency signal lines, and low-frequency signal lines. The signal lines may transmit the device operating voltage (VDD), common ground voltage (VSS), or the voltage of driving device terminal, but the present disclosure is not limited thereto. In accordance with some embodiments, the conductive layer 120a in the redistribution structure 120 may be a dummy pattern, but it is not limited thereto.

It should be understood that the number and type of the TFT units 120T are not limited to those shown in the drawings, and the electronic device may have other suitable numbers or types of thin-film transistors according to different embodiments. The type of the TFT unit 120T may include a top gate thin-film transistor, a bottom gate thin-film transistor, a dual gate (double gate) thin-film transistor, or a combination thereof. In accordance with some embodiments, the TFT unit 120T may be further electrically connected to a capacitor element, but it is not limited thereto. Moreover, the TFT unit 120T may include at least one semiconductor layer, a gate dielectric layer and a gate electrode layer. The semiconductor layer may include single crystal silicon, polycrystalline silicon, low-temperature silicon, oxide semiconductor or a combination thereof, but it is not limited thereto. In addition, the materials of the source electrode and the drain electrode of the TFT unit 120T may be the same as or different from the material of the conductive layer 120a. The TFT unit 120T can exist in various forms known to those skilled in the art, and its detailed structure will not be repeated here.

Furthermore, as shown in FIG. 4, in accordance with some embodiments, the top surface of the conductive pad 110 may be recessed, i.e. have a concave surface. For example, with such a design, the offset of the conductive pad 112 may be reduced.

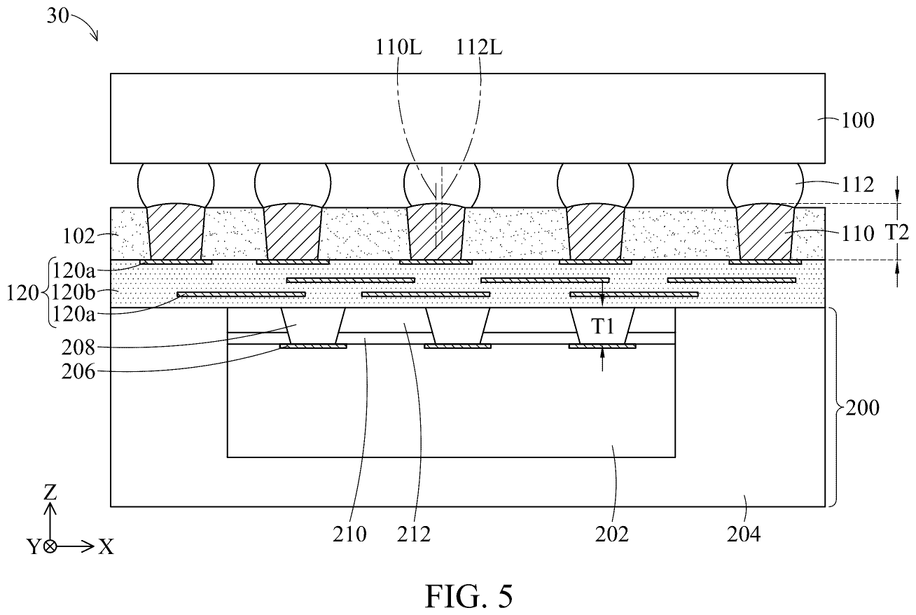

Next, refer to FIG. 5, which is a partial cross-sectional diagram of an electronic device 30 in accordance with some other embodiments of the present disclosure. It should be understood that, some elements of the electronic device 30 may be omitted in the drawings for clarity, and only some elements are schematically shown. In accordance with some embodiments, additional features may be added to the electronic device 30 described below.

As shown in FIG. 5, the connecting member 208 of the packaging structure 200 has a first thickness T1, and the conductive pad 110 has a second thickness T2. In accordance with some embodiments, the second thickness T2 of the conductive pad 110 is greater than the first thickness T1 of the connecting member 208. Specifically, in accordance with some embodiments, the first thickness T1 is between 1 micrometer (μm) and 5 micrometers (μm) (i.e. 1 μm≤first thickness T1≤5 μm). In accordance with some embodiments, the second thickness T2 is between 5 micrometers (μm) and 20 micrometers (μm) (i.e. 5 μm≤second thickness T2≤20 μm). It should be noted that, through the aforementioned configuration, the structural stability after the conductive pad 110 and the conductive pad 112 are bonded can be improved, the heat dissipation effect can be improved, and the electrical connection or reliability can be further improved.

In accordance with the embodiments of the present disclosure, the first thickness T1 refers to the maximum thickness of the conductive pad 110 in the normal direction of the electronic device (for example, the Z direction in the drawing). The second thickness T2 refers to the maximum thickness of the connecting member 208 in the normal direction of the electronic device (for example, the Z direction in the drawing).

In addition, as shown in FIG. 5, in accordance with some embodiments, the top surface of the conductive pad 110 may be protruded, i.e. have a convex surface. The conductive pad 110 may protrude from the top surface of the insulating layer 102. In accordance with some embodiments, the top surface of the conductive pad 110 may be plane, and the plane surface is higher than the top surface of the insulating layer 102. In accordance with some embodiments, the top surface of the conductive pad 110 may be concave, and the concave surface is higher than the top surface of the insulating layer 102, but it is not limited thereto.

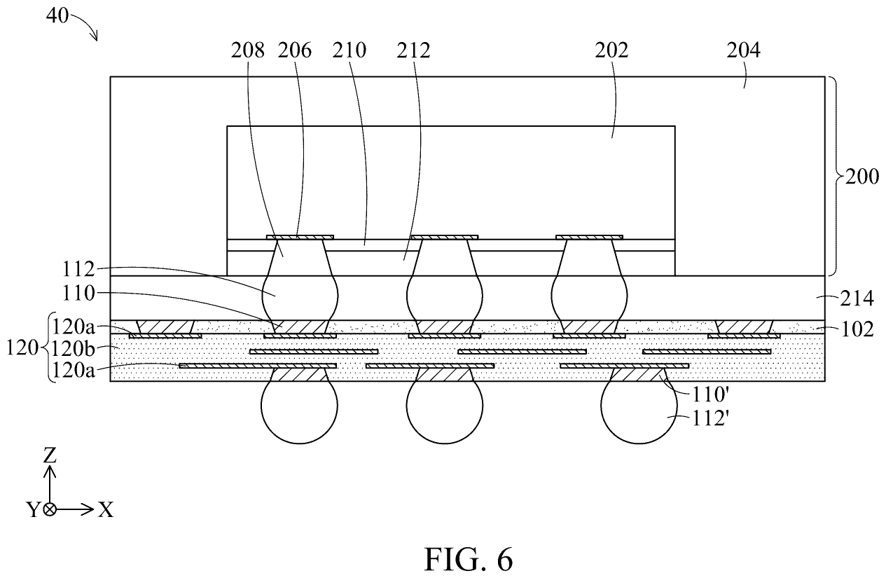

Next, refer to FIG. 6, which is a partial cross-sectional diagram of an electronic device 40 in accordance with some other embodiments of the present disclosure. It should be understood that, some elements of the electronic device 40 may be omitted in the drawings for clarity, and only some elements are schematically shown. In accordance with some embodiments, additional features may be added to the electronic device 40 described below.

As shown in FIG. 6, in accordance with some embodiments, the electronic device 40 is packaged in a redistribution structure first (RDL first) manner. That is, the redistribution structure 120 is formed first, and then the packaging structure 200 including the chip 202 is formed on the redistribution structure 120. In this embodiment, the conductive layer 120a of the redistribution structure 120 can be further electrically connected to a conductive pad 110′ and a conductive pad 112′, and the conductive pad 110′, the conductive pad 112′ and the conductive pad 110, the conductive pad 112 are disposed on opposite sides of the redistribution structure 120, respectively. The materials and forming methods of the conductive pad 110′ and the conductive pad 112′ are the same or similar to those of the aforementioned conductive pad 110 and the conductive pad 112, and thus will not be repeated here. In accordance with some embodiments, the conductive layer 120a in the redistribution structure 120 may be a dummy pattern or may be electrically connected to the ground signal line, but it is not limited thereto. In accordance with some embodiments, the surface of the conductive pad 110′ is substantially aligned with the surface of the insulating layer 102b. For example, along the Z direction, the distance between the surface of the conductive pad 110′ and the surface of the insulating layer 102b may be greater than or equal to 0 micrometers and less than or equal to 5 micrometers. In accordance with some embodiments, the surface of the conductive pad 110′ may protrude from the surface of the insulating layer 102b along the Z direction. In accordance with some embodiments, the surface of the conductive pad 110′ may be recessed from the surface of the insulating layer 102b along the Z direction.

Moreover, the electronic device 40 may further include a protective layer 214, and the protective layer 214 may be disposed between the redistribution structure 120 and the packaging structure 200 and surround the conductive pad 112.

In accordance with some embodiments, the protective layer 214 may be an encapsulation material, which can reduce the influence of water and oxygen in the external environment on the conductive pad 110 and the conductive pad 112, but it is not limited thereto. In accordance with some embodiments, the protective layer 214 may include molding compound, epoxy, another suitable encapsulation material, or a combination thereof, but it is not limited thereto. In accordance with some embodiments, the protective layer 214 may be formed by a compression molding process, a transfer molding process or another suitable method. In accordance with some embodiments, the protective layer 214 may undergo a molding process in a liquid or semi-liquid state, and then be cured.

To summarize the above, in accordance with the embodiments of the present disclosure, the electronic device includes a conductive pad with specific material properties, which can effectively reduce the stress on the heterogeneous interface structure, thereby improving the structural reliability of the electronic device.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a redistribution structure;
an electronic unit; and
a first conductive pad disposed between the redistribution structure and the electronic unit, and the electronic unit is electrically connected to the redistribution structure through the first conductive pad,
wherein the first conductive pad has a first coefficient of thermal expansion and a first Young's modulus, and the first coefficient of thermal expansion and the first Young's modulus conform to the following formula: 0.7×(0.0069E²−1.1498E+59.661)≤CTE≤1.3×(0.0069E²−1.1498E+59.661),
wherein CTE is the first coefficient of thermal expansion, and E is the first Young's modulus in the formula.

2. The electronic device as claimed in claim 1, wherein the first coefficient of thermal expansion of the first conductive pad is greater than or equal to 10 ppm/° C. and less than or equal to 43.6 ppm/° C.

3. The electronic device as claimed in claim 1, wherein the first Young's modulus of the first conductive pad is greater than or equal to 17 GPa and less than or equal to 89 GPa.

4. The electronic device as claimed in claim 1, further comprising:
a second conductive pad disposed between the first conductive pad and the electronic unit.

5. The electronic device as claimed in claim 4, wherein the second conductive pad has a second coefficient of thermal expansion, and the second coefficient of thermal expansion is greater than the first coefficient of thermal expansion.

6. The electronic device as claimed in claim 4, further comprising:
a first insulating layer disposed adjacent to the first conductive pad and the second conductive pad, wherein the first conductive pad is in contact with the first insulating layer and the second conductive pad.

7. The electronic device as claimed in claim 4, wherein the second coefficient of thermal expansion is greater than or equal to 15 ppm/° C. and less than or equal to 30 ppm/° C.

8. The electronic device as claimed in claim 4, wherein the second conductive pad has a first width, and the first conductive pad has a second width, and the first width is greater than the second width.

9. The electronic device as claimed in claim 8, wherein a distance between a centerline of the first conductive pad and a centerline of the second conductive pad does not exceed ⅙ of the first width.

10. The electronic device as claimed in claim 1, further comprising:
a packaging structure electrically connected to the redistribution structure.

11. The electronic device as claimed in claim 10, wherein the packaging structure comprises:
a chip; and
a protective layer surrounding the chip, wherein the protective layer has a third coefficient of thermal expansion, and the third coefficient of thermal expansion is smaller than the first coefficient of thermal expansion.

12. The electronic device as claimed in claim 11, wherein the third coefficient of thermal expansion is greater than or equal to 6 ppm/° C. and less than or equal to 24 ppm/° C.

13. The electronic device as claimed in claim 10, further comprising:
a connecting member disposed between the packaging structure and the redistribution structure, wherein the connecting member has a first thickness, the first conductive pad has a second thickness, and the second thickness is greater than the first thickness.

14. The electronic device as claimed in claim 1, further comprising:
a first insulating layer disposed adjacent to the first conductive pad, wherein the first insulating layer has a fourth coefficient of thermal expansion, and the fourth coefficient of thermal expansion is smaller than the first coefficient of thermal expansion.

15. The electronic device as claimed in claim 14, wherein the fourth coefficient of thermal expansion is greater than or equal to 5 ppm/° C. and less than or equal to 12 ppm/° C.

16. The electronic device as claimed in claim 1, wherein the redistribution structure comprises:
a second insulating layer, wherein the first conductive pad is disposed on the second insulating layer, the second insulating layer has a fifth coefficient of thermal expansion, and the fifth coefficient of thermal expansion is smaller than the first coefficient of thermal expansion.

17. The electronic device as claimed in claim 16, wherein the fifth coefficient of thermal expansion is greater than or equal to 5 ppm/° C. and less than or equal to 25 ppm/° C.

18. The electronic device as claimed in claim 1, wherein the redistribution structure comprises:
a thin-film transistor unit electrically connected to the first conductive pad.

19. The electronic device as claimed in claim 1, wherein the redistribution structure comprises:
at least one conductive layer and at least one insulating layer, and the at least one conductive layer and the at least one insulating layer are stacked alternately.

20. The electronic device as claimed in claim 19, wherein one of the conductive layers is a dummy pattern.
